(19) United States
(12) Patent Application Publication
(10) Pub. No.: US 2025/0391656 A1
(43) Pub. Date: Dec. 25, 2025

(54) LOW-K FILM COEFFICIENT OF THERMAL EXPANSION MODULATION BY UV TREATMENT

(71) Applicant: Applied Materials, Inc., Santa Clara, CA (US)

(72) Inventors: Rui LU, Santa Clara, CA (US); Bo XIE, San Jose, CA (US); Chi-I LANG, Cupertino, CA (US); Li-Qun XIA, Santa Clara, CA (US); Shankar VENKATARAMAN, San Jose, CA (US)

(21) Appl. No.: 18/751,058

(22) Filed: Jun. 21, 2024

(51) Int. Cl. H01L 21/02

(52) U.S. Cl. CPC H01L 21/02348; H01L 21/02164; H01L 21/02211; H01L 21/02216; H01L 21/02274

(57) ABSTRACT

A method for modulating the coefficient of thermal expansion (CTE) of dielectric films on a substrate is provided. In some embodiments, the method includes positioning a substrate within a processing chamber, forming a dielectric film stack on the substrate, and curing the dielectric film with a UV source to modify a CTE of the dielectric film.

### BACKGROUND

### Field

Embodiments described herein generally relate to techniques for processing low-k dielectric films. More specifically, embodiments described herein relate to processes for modulating the coefficient of thermal expansion (CTE) of low-k dielectric films.

### Description of the Related Art

Current demands for faster circuitry with greater circuit densities has driven a great degree of current research and innovation into the materials and processes implemented in the fabrication of such integrated circuits. Minimizing damage of low dielectric constant (low-k) films is an important factor in continuing to decrease feature size and increase circuit densities. However, as feature sizes decrease, damage to the low-k film become a serious challenge.

Integrated circuits that use film stacks which include a low-k film are prone to damage, such as separation of different films in the film stack. Separation may occur after back end of line (BEOL) integration due to different coefficients of thermal expansion (CTE) in the different films in the film stack. In order to maintain the integrity of low-k films, a method to modulate the CTE of the low-k film is needed.

### SUMMARY

Embodiments described herein generally relate to processes for processing dielectric films. More specifically, embodiments described herein relate to processes for modulating the coefficient of thermal expansion (CTE) of low-k dielectric films.

In one embodiment, a method is provided. The method includes positioning a substrate within a processing chamber, forming a dielectric film stack on the substrate, and curing the dielectric film with a UV source to modify a coefficient of thermal expansion (CTE) of the dielectric film.

In another embodiment, a method is provided. The method includes positioning a substrate within a processing chamber, depositing a dielectric film having a first coefficient of thermal expansion (CTE) over the substrate. The deposition includes exposing the substrate to a silicon precursor to form a silicon-containing film and applying a plasma treatment to the silicon-containing film. The method further includes curing the dielectric film with a UV source to decrease the first CTE, wherein the cured dielectric film comprises a second CTE.

In yet another embodiment, a non-transitory computer-readable medium is provided. The non-transitory computer-readable medium includes instructions that, when executed by one or more processors, cause a computer system to perform the following steps. Positioning a substrate within a processing chamber, depositing a dielectric film having a first coefficient of thermal expansion (CTE) over the substrate. The deposition includes exposing the substrate to a silicon precursor to form a silicon-containing film and applying a plasma treatment to the silicon-containing film. The instructions further include the step of curing the dielectric film with a UV source to modify the first CTE, wherein the cured dielectric film comprises a second CTE.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic cross-sectional view of a processing chamber, according to one or more embodiments.

FIG. 2 is a schematic block diagram view of a method of substrate processing, according to one or more embodiments.

FIGS. 3A-3D are partial schematic cross-sectional views of a substrate during a substrate processing method, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein generally relate to techniques for processing low-k dielectric films. More specifically, embodiments described herein relate to processes for modulating the coefficient of thermal expansion (CTE) of low-k dielectric films.

During back end of the line (BEOL) processing operations, films deposited on a substrate may separate, peel, or crack due to films in the film stack having different CTEs. Accordingly, techniques for modulating the CTE of a low-k film described herein reduce or prevent separation, peeling, or cracking due to the resulting CTEs of the films being similar.

A “substrate,” “substrate surface,” or the like, as used herein, refers to any substrate or material surface formed on a substrate upon which processing is performed. For example, a substrate surface on which processing can be performed include, but are not limited to, materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate (or otherwise generate or graft target chemical moieties to impart chemical functionality), anneal and/or bake the substrate surface. In addition to processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface. What a given substrate surface comprises will depend on what materials are to be deposited, as well as the particular chemistry used.

As used in this specification and the appended claims, the terms “reactive compound,” “reactive gas,” “reactive species,” “precursor,” “process gas,” and the like are used interchangeably to mean a substance with a species capable of reacting with the substrate surface or material on the substrate surface in a surface reaction (e.g., chemisorption, oxidation, reduction). For example, a first “reactive gas” may simply adsorb onto the surface of a substrate and be available for further chemical reaction with a second reactive gas.

As used in this specification and the appended claims, the terms “precursor,” “reactant,” “reactive gas” and the like are used interchangeably to refer to any gaseous species that can react with the substrate surface.

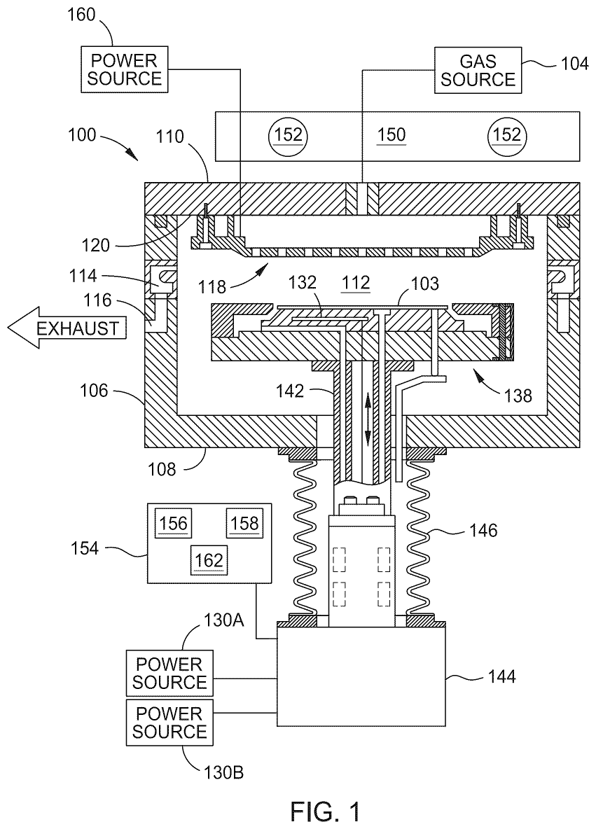

FIG. 1 is a schematic cross-sectional view of a processing chamber 100, such as a CVD processing chamber, that may be used for depositing a silicon based layer according to the embodiments described herein. The processing chamber 100 is available from Applied Materials, Inc. located in Santa Clara, Calif., and a brief description thereof follows. Processing chambers that may be adapted to perform the SiOC layer deposition methods described herein is the PRODUCER® chemical vapor deposition chamber, both available from Applied Materials, Inc. located in Santa Clara, Calif. It is to be understood that the chamber described below is an exemplary embodiment and other chambers, including chambers from other manufacturers, may be used with or modified to match embodiments described herein without diverging from the inventive characteristics described herein.

The processing chamber 100 may be part of a processing system (not shown) that includes multiple processing chambers connected to a central transfer chamber (not shown) and serviced by a robot (not shown). The processing chamber 100 includes walls 106, a bottom 108, and a lid 110 that define a process volume 112. The walls 106 and bottom 108 can be fabricated from a unitary block of aluminum. The lid 110 may be a UV transparent window comprised of quartz or another UV transparent material such as such as sapphire, CaF₂, MgF₂, AlON, a silicon oxide material, a silicon oxynitride material, or another UV-transparent material. In some embodiments, the lid 110 may include holes to allow gas to pass through the lid 110 into the processing chamber 100. The processing chamber 100 may also include a pumping ring 114 that fluidly couples the process volume 112 to an exhaust port 116 as well as other pumping components (not shown).

A substrate support assembly 138, which may be heated, may be centrally disposed within the processing chamber 100. The substrate support assembly 138 supports a substrate 103 during a deposition process. The substrate support assembly 138 generally is fabricated from aluminum, ceramic or a combination of aluminum and ceramic, and includes at least one bias electrode 132.

A UV source 150 is disposed above the lid 110. The UV source 150 is configured to generate UV energy and project the UV energy towards the substrate support assembly 138 through the lid 110, thereby exposing the substrate 103 on the substrate support assembly 138 to UV light. In some embodiments, the UV source 150 may include two cylinder UV bulbs. The UV bulbs may be parallel to each other above the lid 110. A cover (not shown) may be disposed above the UV source 150. In one or more embodiments, the cover may be shaped to assist the projection of the UV energy from the UV source 150 towards the substrate support.

In one or more embodiments, the UV source 150 may include one or more UV lights 152 to generate UV radiation. The UV lights 152 may be lamps, LED emitters, or other UV emitters, where the UV radiation generated is about 100 nm to about 500 nm, such as about 170 nm to about 500 nm. For example, the UV lights 152 may be argon lamps discharging radiation at 126 nm, krypton lamps discharging at 146 nm, xenon lamps discharging at 172 nm, krypton chloride lamps discharging at 222 nm, xenon chloride lamps discharging at 308 nm, mercury lamps discharging at 254 nm or 365 nm, metal vapor lamps such as zinc discharging at 214 nm, rare earth near-UV lamps such as europium-doped strontium borate or fluoroborate lamps discharging at 368-371 nm.

A vacuum port may be used to apply a vacuum between the substrate 103 and the substrate support assembly 138 to secure the substrate 103 to the substrate support assembly 138 during the deposition process. The bias electrode 132, may be, for example, the bias electrode 132 disposed in the substrate support assembly 138, and coupled to a bias power source 130A and 130B, to bias the substrate support assembly 138 and substrate 103 positioned thereon to a predetermined bias power level while processing.

The bias power source 130A and 130B can be independently configured to deliver power to the substrate 103 and the substrate support assembly 138 at a variety of frequencies, such as a frequency between about 1 MHz and about 60 MHz. In one embodiment, the bias power source 130A may be configured to deliver power to the substrate 103 at a frequency of about 2 MHZ, and the bias power source 130B may be configured to deliver power to the substrate 103 at a frequency of about 13.56 MHz. In another embodiment, the bias power source 130A may be configured to deliver power to the substrate 103 at a frequency of 2 MHz, the bias power source 130B may be configured to deliver power to the substrate 103 at a frequency of 13.56 MHZ, and a third power source (not shown) is configured to deliver power to the substrate 103 at a frequency of about 60 MHZ. Various permutations of the frequencies described here can be employed without diverging from the embodiments described herein.

Generally, the substrate support assembly 138 is coupled to a stem 142. The stem 142 provides a conduit for electrical leads, vacuum and gas supply lines between the substrate support assembly 138 and other components of the processing chamber 100. Additionally, the stem 142 couples the substrate support assembly 138 to a lift system 144 that moves the substrate support assembly 138 between an elevated position (as shown in FIG. 1) and a lowered position (not shown) to facilitate robotic transfer. Bellows 146 provide a vacuum seal between the process volume 112 and the atmosphere outside the processing chamber 100 while facilitating the movement of the substrate support assembly 138.

The showerhead 118 may generally be coupled to an interior side 120 of the lid 110. Gases (e.g., process and other gases) that enter the processing chamber 100 from a gas source 104 pass through the showerhead 118 and into the processing chamber 100. The showerhead 118 may be configured to provide a uniform flow of gases to the processing chamber 100. Uniform gas flow is desirable to promote uniform layer formation on the substrate 103. A plasma power source 160 may be coupled to the showerhead 118 to energize the gases through the showerhead 118 towards substrate 103 disposed on the substrate support assembly 138. The plasma power source 160 may provide RF power. Further, the plasma power source 160 can be configured to deliver power to the showerhead 118 at a variety of frequencies, such as a frequency between about 100 kHz and about 40 MHz. In one embodiment, the plasma power source 160 is configured to deliver power to the showerhead 118 at a high frequency radio frequency (HFRF) of 13.56 MHZ.

The function of the processing chamber 100 can be controlled by a computing device 154. The computing device 154 may be one of any form of general purpose computer that can be used in an industrial setting for controlling various chambers and sub-processors. The computing device 154 includes a computer processor 156. The computing device 154 includes memory 158. The memory 158 may include any suitable memory, such as random access memory, read only memory, flash memory, hard disk, or any other form of digital storage, local or remote. The computing device 154 may include various support circuits 162, which may be coupled to the computer processor 156 for supporting the computer processor 156 in a conventional manner. Software routines, as required, may be stored in the memory or executed by a second computing device (not shown) that is remotely located.

The computing device 154 may further include one or more computer readable media (not shown). Computer readable media generally include any device, located either locally or remotely, which is capable of storing information that is retrievable by a computing device. Examples of computer readable media useable with embodiments of the present embodiments include solid state memory, floppy disks, internal or external hard drives, and optical memory (CDs, DVDs, BR-D, etc). In one embodiment, the memory 158 may be the computer readable media. Software routines may be stored on the computer readable media to be executed by the computing device.

The software routines, when executed, transform the general purpose computer into a specific process computer that controls the chamber operation so that a chamber process is performed. Alternatively, the software routines may be performed in hardware as an application specific integrated circuit or other type of hardware implementation, or a combination of software and hardware.

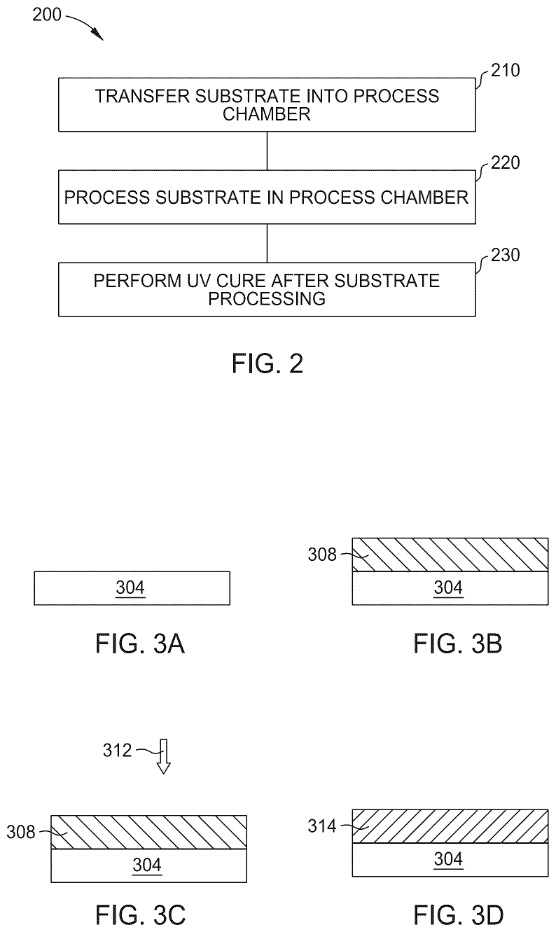

FIG. 2 is a schematic block diagram of a substrate processing method 200. FIGS. 3A-3D are partial schematic cross-sectional views of a substrate during the substrate processing method 200.

At operation 210, a substrate 304 is transferred into a processing chamber (e.g., processing chamber 100). In various embodiments, the substrate 304 is positioned on a substrate support in a processing chamber capable of performing plasma enhanced chemical vapor deposition (PECVD) (e.g., processing chamber 100).

At operation 220, as seen in FIG. 3B, a dielectric film, such as low-k film 308, is deposited onto the substrate 304. During operation 220, one or more silicon precursors are introduced to the processing chamber 100. The one or more silicon precursors can be flowed into the processing chamber 100 at a flow rate of about 10 mg/minute to about 3000 mg/minute. In some embodiments, the silicon precursor that is introduced into the processing chamber 100 is a silicon compound including a silicon-containing component, where a silicon atom is bonded to at least one of a carbon atom and/or an oxygen atom. In at least one embodiment, the silicon containing component may include any one or more organosilicon based compound, such as octamethylcyclotetrasiloxane, 2,4,6,8-tetramethyl-2,4,6,8-tetravinylcyclotetrasiloxane, 2,4,6,8-tetramethylcyclotetrasiloxane, and combinations thereof.

In at least one embodiment, the silicon containing component may include any one or more organosilicon based compound, such as dimethyldimethoxysilane, ethoxydimethylsilane, isobutylmethyldimethoxysilane, vinylmethyldimethoxysilane, and combinations thereof.

In at least one embodiment, the silicon containing component may include any one or more organosilicon based compound, such as 1,1,3,3-tetramethyl-1,3-dimethoxydisiloxane, 1,3-dimethyl-1,1,3,3-tetramethoxydisiloxane, and combinations thereof.

In at least one embodiment, the silicon containing component may include any one or more organosilicon based compound, such as methoxy(dimethyl)silylmethane, methyl(dimethoxy)silylmethane, bis(trimethylsilyl)methane, 1,3-diethoxy-1,3-dimethyl-1,3-disilacyclobutane, 1,3-dimethyl-1,3-diphenyl-1,3-disilacyclobutane, and combinations thereof.

The deposition process of operation 220 low-k film 308 may be deposited via one or more of chemical vapor deposition (CVD) processes, physical vapor deposition (PVD) processes, atomic layer deposition (ALD) processes, PECVD processes, and a combination thereof. An inert carrier gas, such as a noble gas (e.g., argon or helium) may be introduced to the processing chamber 100 with the one or more organosilicon compounds. The carrier gas can include a flow rate of about 50 sccm to about 5000 sccm. In some embodiments, an oxidizing gas may be additionally introduced into the processing chamber 100. The one or more organosilicon compounds and, optionally, the oxidizing gas, can be reacted in the presence of radio frequency (RF) power to deposit a dielectric film, such as low-k film 308 over the substrate 304 in the processing chamber. In various embodiments, the low-k film 308 includes a first CTE between about 10 ppm/C and about 60 ppm/C, such as about 20 ppm/C and about 25 ppm/C, such as about 21 ppm/C and about 24 ppm/C.

In some embodiments, the oxidizing gases are oxygen containing compounds selected from the group of oxygen (O₂), nitrous oxide (N₂O), ozone (O₃), water (H₂O), carbon dioxide (CO₂), carbon monoxide (CO), and combinations thereof.

In operation 220, a gas mixture having a composition including one or more organosilicon compounds, and optionally the oxidizing gas, is introduced into the processing chamber 100 through a gas distribution plate of the chamber, such as a showerhead 118. A RF power is applied to an electrode, such as the showerhead, in order to provide plasma processing conditions in the chamber. The gas mixture is reacted in the chamber in the presence of RF power to deposit a low-k film 308 comprising a silicon oxide layer that adheres strongly to the underlying substrate 304. The RF source may comprise a high frequency radio frequency (HFRF) power source, such as a 13.56 MHz RF generator, and a low frequency radio frequency (LFRF) power source, such as a 200 kHz RF generator. The LFRF power source provides both low frequency generation and fixed match elements. The HFRF power source is designed for use with a fixed match and regulates the power delivered to the load, reducing or eliminating concerns about forward and reflected power. The HFRF includes a power range of about 50 W to about 1000 W. The LFRF includes a power range of about 10 W to about 200 W.

In various embodiments, the pressure of the processing chamber is maintained at about 0.5 Torr to about 500 Torr throughout at least one of the plasma treatment processes, such as about 1 Torr to about 250 Torr, such as about 5 Torr to about 150 Torr. The temperature within the processing chamber is maintained at about 100° C. to about 450° C. throughout at least one of the plasma treatment processes, such as about 150° C. to about 400° C., such as about 200° C. to about 350° C.

In other embodiments, the deposition process of operation 220 can begin with the deposition of a copper film (not pictured). The deposition of the copper film 306 may be deposited via one or more of chemical vapor deposition (CVD) processes, physical vapor deposition (PVD) processes, atomic layer deposition (ALD) processes, PECVD processes, and a combination thereof. In some embodiments, a copper precursor (e.g., a first reactive precursor gas comprising a copper containing organometallic) and a hydrogen precursor (e.g., a second reactive precursor comprising hydrogen gas) enter the processing chamber 100. The copper precursor and the hydrogen precursor can be flowed into the processing chamber 100 at a flow rate of about 10 mg/minute to about 3000 mg/minute. The substrate 304 is sequentially exposed to the copper precursor and the hydrogen precursor. The copper precursor and the hydrogen precursor react to form a copper film (not pictured) on the substrate 304 in the processing chamber 100. The copper film (not pictured) can include a CTE between about 10 ppm/C and about 13 ppm/C. After the reaction, any remaining copper precursor and/or remaining hydrogen precursor is purged from the processing chamber 100. In some embodiments, a low-k film (e.g., the low-k film 308) may be deposited over the copper film to form a film stack.

At operation 230, as seen in FIG. 3C, the low-k film 308 is exposed to a UV cure 312. In some embodiments, prior to exposure to the UV cure 312, the substrate 304 may be moved to a second processing chamber for UV processing. The low-k film 308 that includes a first CTE between about 10 ppm/C and about 60 ppm/C, such as about 20 ppm/C and about 25 ppm/C, such as about 21 ppm/C and about 24.7 ppm/C is exposed to the UV cure 312. The low-k film 308 is exposed to the UV cure for about 78 seconds to about 360 seconds, such as about 90 seconds or such as about 126 seconds. The UV cure 312 includes a wavelength between about 100 nm and about 450 nm. The UV power is calculated using the UV intensity level. When the UV intensity is fully radiated it is functioning at 100%. In this embodiment, the UV intensity can be between about 80% and about 95%. The UV light used in the UV cure 312 may be emitted from the UV source 150 seen in the processing chamber 100.

The UV cure 312 increases the amount of cross-linking between the Si—O—Si bonds included in the low-k film 308. The increased cross-linking modulates the CTE of the low-k film 308, resulting in a reduced CTE of the low-k film 308. The UV cure 312 decreases the CHx bonds in the low-k film 308 by breaking the bonds between the molecules in the silicon precursor. When the CHx bonds break in a silicon precursor, the CHx bonds of the silicon precursor release a silicon, which is then free to make a new bond such as a Si—O—Si. Thus, as the CHx bonds decrease, the Si—O—Si bonds increase in a cage network caused by the cross-linking of the Si—O—Si bonds. The cross-linking bonds causes the first CTE of the low-k film 308 to decrease to a second CTE low-k film 314, as seen in FIG. 3D. The second CTE low-k film 314 includes a CTE between about 4 ppm/C and about 13 ppm/C, such as about 10 ppm/C or such as about 13 ppm/C. In some embodiments, the low-k film 308 is exposed to the UV cure 312 until the first CTE is modulated to a desired second CTE. The result of the UV cure 312, as seen in FIG. 3D, includes the second CTE low-k film 314, which includes a CTE between about 4 ppm/C and about 60 ppm/C, such as about 10 ppm/C and about 13 ppm/C. The second CTE low-k film 314 is disposed over the substrate 304.

In various embodiments, the pressure of the processing chamber is maintained at about 0.5 Torr to about 500 Torr throughout the UV cure 312, such as about 1 Torr to about 250 Torr, such as about 5 Torr to about 150 Torr. In various embodiments, the temperature within the processing chamber is maintained at about 100° C. to about 450° C. throughout the UV cure 312, such as about 150° C. to about 400° C., such as about 200° C. to about 350° C.

Overall, various embodiments of the present disclosure provide methods of preparing thin, low-k films from silicon precursors and modulating the CTEs of the low-k films. In particular, a low-k film is exposed to a UV cure to modulate the CTE of the low-k film by increasing the amount of cross-linking between the Si—C—Si and Si—O—Si bonds included in the low-k film. The increased cross-linking decreases the CTE of the low-k film. It was found that a low-k film having a modulated CTE decreases the likelihood that the low-k film and the copper film will separate, crack, or peel during BEOL processing.

While the present disclosure has been described with respect to a number of embodiments and examples, those skilled in the art, having benefit of this disclosure, will appreciate that other embodiments can be devised which do not depart from the scope and spirit of the present disclosure.

What is claimed is:

1. A method, comprising:
positioning a substrate within a processing chamber;
forming a dielectric film on the substrate; and
curing the dielectric film with a UV source to modify a coefficient of thermal expansion (CTE) of the dielectric film.

2. The method of claim 1, wherein the substrate comprises silicon.

3. The method of claim 1, wherein forming the dielectric film comprises:
exposing the substrate to a silicon precursor to form a silicon-containing film;
purging the processing chamber of the silicon precursor; and
applying a plasma treatment to the silicon-containing film to form the dielectric film over the substrate.

4. The method of claim 3, wherein applying the plasma treatment comprises providing a radio frequency (RF) power to the processing chamber to generate a plasma.

5. The method of claim 4, wherein the silicon precursor comprises octamethylcyclotetrasiloxane, 2,4,6,8-tetramethyl-2,4,6,8-tetravinylcyclotetrasiloxane, 2,4,6,8-tetramethylcyclotetrasiloxane, or combinations thereof.

6. The method of claim 4, wherein the silicon precursor comprises dimethyldimethoxysilane, ethoxydimethylsilane, isobutylmethyldimethoxysilane, vinylmethyldimethoxysilane, or combinations thereof.

7. The method of claim 4, wherein the silicon precursor comprises 1,1,3,3-tetramethyl-1,3-dimethoxydisiloxane, 1,3-dimethyl-1,1,3,3-tetramethoxydisiloxane, or combinations thereof.

8. The method of claim 4, wherein the silicon precursor comprises methoxy(dimethyl)silylmethane, methyl(dimethoxy)silylmethane, bis(trimethylsilyl)methane, 1,3-diethoxy-1,3-dimethyl-1,3-disilacyclobutane, 1,3-dimethyl-1,3-diphenyl-1,3-disilacyclobutane, or combinations thereof.

9. The method of claim 1, further comprising:
transferring the substrate to a second processing chamber for UV processing before curing the dielectric film with the UV source.

10. The method of claim 1, wherein the dielectric film has a dielectric constant that is less than silicon dioxide.

11. The method claim 1, wherein the CTE of the dielectric film is about 20 ppm/C to about 25 ppm/C before curing the dielectric film with the UV source.

12. The method of claim 1, wherein curing the dielectric film with the UV source decreases the CTE.

13. The method of claim 1, wherein the UV source provided to the processing chamber has a wavelength of about 100 nm to about 450 nm.

14. The method of claim 1, wherein the dielectric film is cured for about 78 seconds to about 340 seconds.

15. The method of claim 1, wherein the CTE of the dielectric film is about 10 ppm/C to about 13 ppm/C after curing the dielectric film with the UV source.

16. A method of forming a film, comprising:
positioning a substrate within a processing chamber;
depositing a dielectric film having a first coefficient of thermal expansion (CTE) over the substrate, comprising:
exposing the substrate to a silicon precursor to form a silicon-containing film; and
applying a plasma treatment to the silicon-containing film; and
curing the dielectric film with a UV source to decrease the first CTE, wherein the cured dielectric film comprises a second CTE.

17. The method of claim 16, wherein the silicon precursor are introduced to the processing chamber at a flow rate of about 10 mg/minute to about 3000 mg/minute.

18. The method of claim 16, wherein the first CTE is about 20 ppm/C to about 25 ppm/C.

19. The method of claim 16, wherein the second CTE is about 10 ppm/C to about 13 ppm/C after the dielectric film is cured with a UV source.

20. One or more non-transitory computer-readable media storing instructions that, when executed by one or more processors, cause a computer system to perform the steps of:
positioning a substrate within a processing chamber;
depositing a dielectric film having a first coefficient of thermal expansion (CTE) over the substrate, comprising:
exposing the substrate to a silicon precursor to form a silicon-containing film; and
applying a plasma treatment to the silicon-containing film; and
curing the dielectric film with a UV source to modify the first CTE, wherein the cured dielectric film comprises a second CTE.
